(19) United States
(12) Patent Application Publication
(10) Pub. No.: US 2021/0359064 A1
(43) Pub. Date: Nov. 18, 2021

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Kunpeng HE, Shenzhen (CN); Jia TANG, Shenzhen (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 16/626,345

(22) PCT Filed: Nov. 8, 2019
(86) PCT No.: PCT/CN2019/116715

§ 371 Date: Dec. 24, 2019

(30) Foreign Application Priority Data
Aug. 15, 2019 (CN) 201910754628.3

(51) Int. Cl. H01L 27/32; H01L 51/56

(52) U.S. Cl. CPC H01L 27/3272; H01L 2227/323; H01L 51/56; H01L 27/3276

(57) ABSTRACT

A display panel including a base, a metal wire layer, an organic light-emitting diode (OLED) luminous layer, and a blocking layer. The blocking layer is disposed between the metal wire layer and the OLED luminous layer. The blocking layer covers the metal wire layer. Through disposing the blocking layer that can absorb UV light on metal wires, UV light of an exposure machine is prevented from irradiating onto the metal wires of a bottom layer, thereby preventing underlying light from being reflected onto a planarization layer, which reduces a risk of short circuiting or performance abnormality of OLED components due to unevenness of film layers in pixels.

### FIELD OF INVENTION

The present disclosure relates to the field of display technologies, particularly to a display panel and a manufacturing method thereof.

### BACKGROUND OF INVENTION

With development of organic light-emitting diode (OLED) technologies, there are two kinds of manufacturing method for OLED components: evaporating and printing. A thickness between an anode and a cathode of the OLED component is thinner, usually between 100 to 500 nm, thus evenness of a base for manufacturing OLED components stands an important role to prevent the OLED components from short circuiting or abnormal performance due to excessively large or steep inner stage differences in pixel defining layers.

In order to planarize the stage differences in pixel defining layers, a planarization layer is disposed after thin-film transistors are formed. In general, materials of the planarization layer are organic photosensitive photoresists. Thin-film transistors utilize a large amount of metal wires. Metals with high reflectivity are exposed on a side surface of the metal wires. The exposed metal reflects ultraviolet (UV) light irradiated by exposure machines. The reflected light makes the planarization layer absorb a certain amount of light energy, thereby parts of film thickness of the planarization layer are affected. A burr-like convex is formed on a surface of a negative planarization layer or a concave is formed on a surface of a positive planarization layer. Severe convex or concave can affect the performance of the OLED components, and even cause short circuiting in the OLED components.

As shown in FIG. 1, a metal film deposited on a base 10′ is wet etched to form metal wires 20′. Side surfaces 21′ of the metal wires 20′ have burrs which expose a metal having a high reflectance. The exposed metal reflects the light irradiated by exposure machines above thin-film transistor components. A planarization layer 30′ receives the reflected light energy, thus a portion of a film layer of the negative planarization layer 30′ forms the burr-like convex.

An anode 40′, a pixel defining layer 50′, a luminescent material layer 60′, and a cathode 70′ are sequentially formed on the planarization layer 30′. Because the convex is formed on the surface of the planarization layer 30′, an uneven anode 40′ is formed on the surface of the planarization layer 30′. Thus, the convex anode 40′ increases the risk of short circuiting between the cathode 70′ and the anode 40′.

### SUMMARY OF INVENTION

The present disclosure provides a display panel and a manufacturing method thereof to solve problems of existing display panels resulted from short circuit of organic light-emitting diode (OLED) components due to ultraviolet (UV) light reflected by a burr-like convex on sides of metal wires makes the planarization layer absorb a certain amount of light energy, thereby parts of film thickness of the planarization layer are affected, and a burr-like convex is formed on a surface of a negative planarization film layer or a concave is formed on a surface of a positive planarization layer because thin-film components utilize a large amount of the metal wires.

To solve the above-mentioned problems, the present disclosure provides the following technical solutions.

The present disclosure provides a display panel including a base, a metal wire layer disposed on the base, an OLED luminous layer disposed on the metal wire layer, a blocking layer, and a planarization layer. The metal wire layer includes a plurality of metal wires. The blocking layer is disposed between the metal wire layer and the OLED luminous layer. The planarization layer is disposed between the blocking layer and the OLED luminous layer. The blocking layer covers the metal wire layer. A material of the blocking layer comprises an ultraviolet absorbing photoresist.

In one embodiment of the present disclosure, the blocking layer is a patterned net structure. Net wires of the blocking layer cover the metal wires of the metal wire layer.

In one embodiment of the present disclosure, the blocking layer is a layered film stature having an entire surface.

In one embodiment of the present disclosure, a passivation layer is disposed on a side of the metal wire layer facing from the base.

The present disclosure further provides a display panel including a base, a metal wire layer disposed on the base, an OLED luminous layer disposed on the metal wire layer, and a blocking layer. The metal wire layer includes a plurality of metal wires. The blocking layer is disposed between the metal wire layer and the OLED luminous layer. The blocking layer covers the metal wire layer.

In one embodiment of the present disclosure, the display further comprises a planarization layer disposed between the blocking layer and the OLED luminous layer.

In one embodiment of the present disclosure, the blocking layer is a patterned net structure, and net wires of the blocking layer cover the metal wires of the metal wire layer.

In one embodiment of the present disclosure, the blocking layer is a layered film stature having an entire surface.

In one embodiment of the present disclosure, a material of the blocking layer comprises an ultraviolet absorbing photoresist.

In one embodiment of the present disclosure, a passivation layer is disposed on a side of the metal wire layer facing from the base.

The present disclosure further provides a manufacturing method of a display panel comprising the following steps.

A step S10: providing a base, wherein a metal wire layer is disposed on the base.

A step S20: forming a blocking layer in the metal wire layer, wherein the blocking layer covers the metal wire layer.

A step S30: forming an organic light-emitting diode (OLED) luminous layer on the blocking layer.

In one embodiment of the present disclosure, n the step S20, the blocking layer is a patterned net structure, and net wires of the blocking layer cover the metal wires of the metal wire layer.

In one embodiment of the present disclosure, before the step S30, the manufacturing method further comprises: forming a planarization layer on the blocking layer.

In one embodiment of the present disclosure, a material of the blocking layer comprises an ultraviolet absorbing photoresist.

In one embodiment of the present disclosure, the blocking layer is a layered film stature having an entire surface.

In one embodiment of the present disclosure, before the step S20, the manufacturing method further comprises: forming a passivation layer on the metal wire layer.

The beneficial effect of the present disclosure is: the metal wires located in lower layer are prevented from UN light of the exposure machine by disposing the blocking layer. The bottom layer does not reflect to the planarization layer so that burr-like convex or concave resulted from abnormal light energy reception is not formed on the planarization layer during the following manufacture process of the planarization layer. As a result, the evenness of the pixel regions is improved, thereby greatly reducing the risk of short circuit or performance abnormality of the OLED components due to unevenness of the film layer in the pixel regions.

### DESCRIPTION OF DRAWINGS

In order to clarify embodiments or technical solutions of the present technologies, the required drawings of the embodiments or the technical solutions will be briefly described below. Obviously, the drawings in the following description are merely parts of embodiments. Additional drawings may be obtained by a skilled person in the art without creative effort according to the following drawings.

FIG. 1 illustrates a structural diagram of a display panel of present technologies.

FIG. 2 illustrates a structural diagram of a display panel of a first embodiment of the present disclosure.

FIG. 3 illustrates a manufacturing flow chart of the display panel of the present disclosure.

FIG. 4-7 illustrate structural diagrams of a manufacturing method of the first embodiment of the display panel of the present disclosure.

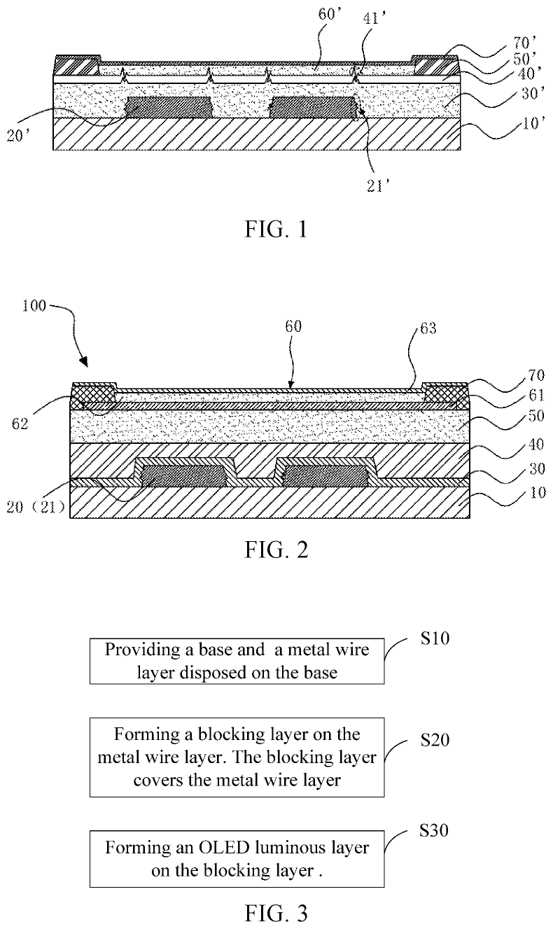

### DETAILED DESCRIPTION OF PREFERRED EMBODIMENTS

The following description of the various embodiments is provided with reference of drawings to illustrate specific embodiments. Directional terms mentioned in the present disclosure, such as upper, lower, front, back, left, right, inside, outside, lateral, etc., are only referring to the direction of the drawing. Therefore, the directional terms used to describe and clarify the present disclosure should not be viewed as limitations of the present disclosure. In the drawing, structurally similar elements are denoted by the same reference numbers.

The present disclosure focus on existing display panels which utilize a large amount of metal in the thin-film transistor components. Metal wires have burr-like convex on the sides which reflects the ultraviolet (UV) light of exposure machines. The planarization layer is organic photosensitive photoresist which absorbs the light energy of the reflected light, thereby parts of film thicknesses of the planarization layer are affected. The convex or a concave on surfaces of the planarized layer may affect the performance of organic light-emitting diode (OLED) components and even lead OLED components to short circuit, thereby causing technical problems due to affected display quality. The present embodiment can solve the problems.

As shown in FIG. 2, the embodiment provides a display panel including a base 10, a metal wire layer 20, a blocking layer 40, an OLED luminous layer 60, and a planarization layer 50.

The metal wire layer 20 is disposed on the base. The OLED luminous layer 60 is disposed on the metal wire layer 20. The blocking layer 40 is disposed between the metal wire layer 20 and the OLED luminous layer.

The metal wire layer 20 includes a plurality of metal wires. The blocking layer 10 covers all the metal wires 21 of the metal wire layer 20.

Because the patterned metal wires 21 are formed by wet etching, a metal film layer having a high reflectance is exposed on sides of the metal wires 21. A burr-like convex is formed and reflects UV light from an exposure machine located above. The blocking layer 40 is disposed above the metal wire layer 20 to absorb the UV light to prevent the UV light from irradiating to the metal wires 21 located below. UV light reflected from bottom is prevented from irradiating to the planarization layer 50 during a manufacturing process of the planarization layer 50, thereby planarization layer preventing the local film thickness of the planarization layer 50 from being affected. As a result, a flatter substrate is provided for manufacturing the OLED components.

The metal wires 21 may be one or more than one of a source, a drain, a gate, a data line, a scan line, etc. The plurality of metal wires 21 may be layered according to specific requirement. Correspondingly, while the plurality of metal wires 21 are layered structure, the metal wire layer 20 is a multi-layer structure. The blocking layer 40 is disposed on the metal wire layer 20 away from the base 10 in the metal of the multi-layer structure to ensure that the blocking layer 40 can cover all of the metal wires 21.

The material of the blocking layer 40 is a photoresist material that strongly absorbs UV light, and may also be other photoresist materials having low reflectance in dark color which can prevent metal of lower layers from being irradiated by UV light.

The planarization layer 50 is disposed between the blocking layer 40 and the OLED luminous layer 60. The planarization layer 50 provides a flat base for the OLED luminous layer 60.

In this embodiment, the blocking layer 40 is a layered film structure having an entire surface and is entirely covered on the metal wire layer 20.

In other embodiment, the blocking layer 40 can by a patterned net structure but it has to be ensured that net wires of the blocking layer cover all the metal wires 21 of the metal wire layer 20.

If the blocking layer 40 is a full-face design and the upper surface is flattened, the planarization layer 50 is not required to be disposed.

The blocking layer 40 can be directly used as a flat substrate for the OLED device to be fabricated on its surface;

If the blocking layer 40 has entire surface structure and flatter surface, the planarization layer 50 is no longer required. The blocking layer 40 can be the flat base for manufacturing OLED components.

A passivation layer 30 is disposed on a side of the metal wire layer 20 facing away from the base. The passivation layer 30 is utilized to protect the metal wires of the metal wire layer 20.

The OLED luminous layer 60 includes an anode 61, an organic luminous material layer 62, and a cathode 63 that are sequentially disposed on the planarization layer 50.

The display panel 100 further includes the pixel defining layer 70 disposed on the planarization layer 50. The pixel defining layer 70 is configured to define pixel regions to make the organic light emitting material layer 62 be evaporated in the pixel regions.

As shown in FIG. 3, this embodiment provides a manufacturing method of the display panel which includes the following steps.

As shown in FIG. 4, step S20 is providing the base 10 provided with the metal wire layer 20.

More particularly, the base 10 may be a glass substrate or a flexible substrate such as polyimide substrate. The metal wire layer 20 includes a plurality of metal wires 21, such as source electrodes, drain electrodes, data lines, etc.

Step S20: forming the blocking layer 40 in the metal wire layer 20. The blocking layer 40 covers the metal wire layer 20.

Before the step S20, forming the blocking layer 40 in the metal wire layer 20 further includes the passivation layer 30. The material of the passivation layer 30 is, but not limited to, silicon oxide.

In the step S20, photoresist materials which can absorb UV light are deposited on the entire surface of the passivation layer 30 and are covered on the metal wire layer 20 for forming the blocking layer 40.

In other embodiments, the blocking layer 40 is patterned to form a net structure. The net structure of the blocking layer 40 entirely covers the metal wires of the metal wire layer 20 to ensure that the blocking layer 40 can prevent the lower metal layers from invasion of UV light.

Step S30: forming an OLED luminous layer 60 on the blocking layer 40.

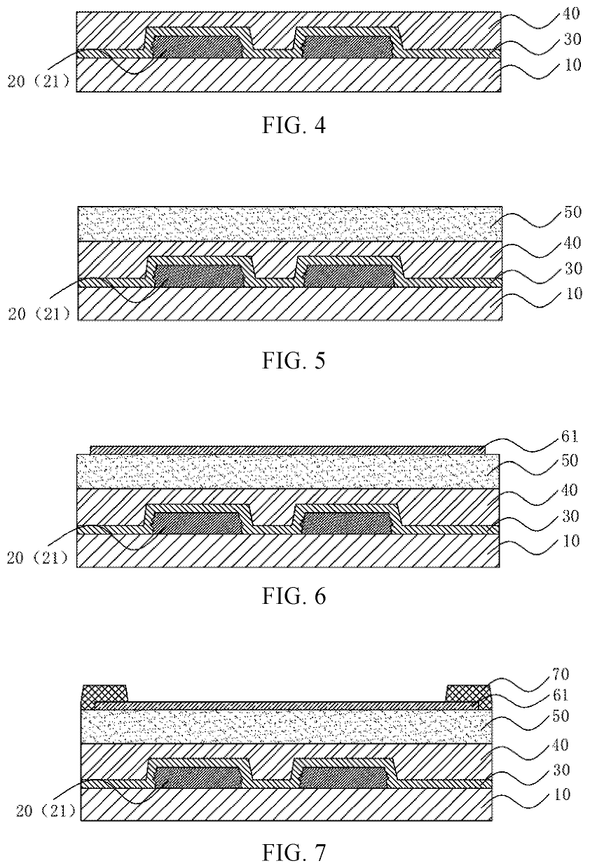

As shown in FIG. 5, before the step S30, the planarization layer 50 is formed on the blocking layer 40 in order to provide a flat base for following manufacturing processes of the OLED luminous layer 60.

During the manufacturing of the planarization layer 50, the bottom layer does not reflect the UV light of the exposure machine due to the deposition of the blocking layer 40 so that burr-like convex or concave resulted from abnormal light energy reception is not formed on the planarization layer 50. As a result, the evenness of the pixel regions is improved, thereby greatly reducing the risk of short circuiting or performance abnormality due to unevenness of the film layer in the pixel regions.

As shown in FIG. 6 and FIG. 7, in the step S30, the anode 61 is firstly formed on the planarization layer 50. The anode 61 is, but not limit to, an indium tin oxide, a laminated structure of indium tin oxide, or other metal layered structure. The evenness of the film layer provided with the anode 61 is improved because the evenness of the planarization layer 50 is improved.

Next, the pixel defining layer 70 is formed on the planarization layer 50. The pixel defining layer 70 defines pixel regions. The pixel defining layer 70 may be, but not limit to, a positive photosensitive photoresist or a negative photosensitive photoresist.

Then, the organic luminous material layer 62 is formed on the anode 61 located in the pixel regions.

Last, the cathode 63 is formed on the organic luminous material layer 62. The cathode 63 is a metal or alloy of aluminum, silver, magnesium, etc.

Beneficial effects: The bottom layer does not reflect to the planarization layer so that burr-like convex or concave resulted from abnormal light energy reception is not formed on the planarization layer during the following manufacturing process of the planarization layer. As a result, the evenness of the pixel regions is improved, thereby greatly reducing the risk of short circuiting or performance abnormality of the OLED components due to unevenness of the film layer in the pixel regions.

To conclude, although the present disclosure has been disclosed by above-mentioned preferred embodiments, the above-mentioned preferred embodiments are not limitations to the present disclosure. Variations and modifications can be obtained by a person skilled in the art without departing from the aspect and scope of the present disclosure. Therefore, the protected scope of the present disclosure is subject to the defined scope of claims.

What is claimed is:

1. A display panel, comprising:
a base;
a metal wire layer disposed on the base and comprising a plurality of metal wires;
an organic light-emitting diode (OLED) luminous layer disposed on the metal wire layer;
a blocking layer disposed between the metal wire layer and the OLED luminous layer; and
a planarization layer disposed between the blocking layer and the OLED luminous layer; wherein
the blocking layer covers the metal wire layer, and a material of the blocking layer comprises an ultraviolet absorbing photoresist.

2. The display panel according to claim 1, wherein the blocking layer is a patterned net structure, and net wires of the blocking layer cover the metal wires of the metal wire layer.

3. The display panel according to claim 1, wherein the blocking layer is a layered film structure having an entire surface.

4. The display panel according to claim 1, wherein a passivation layer is disposed on a side of the metal wire layer facing away from the base.

5. A display panel, comprising:
a base;
a metal wire layer disposed on the base and comprising a plurality of metal wires;
an organic light-emitting diode (OLED) luminous layer disposed on the metal wire layer; and
a blocking layer disposed between the metal wire layer and the OLED luminous layer; wherein
the blocking layer covers the metal wire layer.

6. The display panel according to claim 5, wherein the display panel further comprises a planarization layer disposed between the blocking layer and the OLED luminous layer.

7. The display panel according to claim 6, wherein the blocking layer is a patterned net structure, and net wires of the blocking layer cover the metal wires of the metal wire layer.

8. The display panel according to claim 5, wherein the blocking layer is a layered film structure having an entire surface.

9. The display panel according to claim 5, wherein a material of the blocking layer comprises an ultraviolet absorbing photoresist.

10. The display panel according to claim 1, wherein a passivation layer is disposed on a side of the metal wire layer facing away from the base.

11. A manufacturing method of a display panel, comprising following steps:
step S10: providing a base, wherein a metal wire layer is disposed on the base;
step S20: forming a blocking layer on the metal wire layer, wherein the blocking layer covers the metal wire layer; and
step S30: forming an organic light-emitting diode (OLED) luminous layer on the blocking layer.

12. The manufacturing method according to claim 11, wherein in the step S20, the blocking layer is a patterned net structure, and net wires of the blocking layer cover the metal wires of the metal wire layer.

13. The manufacturing method according to claim 12, wherein before the step S30, the manufacturing method further comprises forming a planarization layer on the blocking layer.

14. The manufacturing method according to claim 11, wherein a material of the blocking layer comprises an ultraviolet absorbing photoresist.

15. The manufacturing method according to claim 11, wherein the blocking layer is a layered film structure having an entire surface.

16. The manufacturing method according to claim 11, wherein before the step S20, the manufacturing method further comprises forming a passivation layer on the metal wire layer.
